(19) United States
(12) Patent Application Publication
(10) Pub. No.: US 2012/0037230 A1
(43) Pub. Date: Feb. 16, 2012

(54) ELECTROLYTE FOR PHOTOELECTRIC CONVERSION ELEMENTS, AND PHOTOELECTRIC CONVERSION ELEMENT AND DYE-SENSITIZED SOLAR CELL USING THE ELECTROLYTE

(75) Inventor: Tsukasa Maruyama, Kanagawa (JP)

(73) Assignee: THE YOKOHAMA RUBBER CO., LTD., MINATO-KU, TOKYO (JP)

(21) Appl. No.: 13/266,840

(22) PCT Filed: Apr. 21, 2010
(86) PCT No.: PCT/JP2010/057079

§ 371 Date: Oct. 28, 2011

(30) Foreign Application Priority Data
Apr. 30, 2009 (JP) 2009-111134

(51) Int. Cl. H01L 51/46

(52) U.S. Cl. 136/263

(57) ABSTRACT

An object of the present invention is to provide an electrolyte for a photoelectric conversion element that can achieve superior heat resistance, and a photoelectric conversion element and a dye-sensitized solar cell using the electrolyte. The electrolyte for a photoelectric conversion element of the present invention includes an organic salt compound (A) containing a tertiary or quaternary cation. Additionally, at least an organic salt compound (a1) containing a tertiary or quaternary cation and a thiocyanate anion is used as the organic salt compound (A).

### TECHNICAL FIELD

The present invention relates to an electrolyte for photoelectric conversion elements, and a photoelectric conversion element and a dye-sensitized solar cell using the electrolyte.

### BACKGROUND ART

In recent years, environmental issues such as global warming and the like that are attributed to increases in carbon dioxide have become serious. As a result, non-silicon solar cells have gained attention as solar cells that have little environmental impact and that also allow for reduced manufacturing costs; and research and development of such is moving forward.

Among non-silicon solar cells, the dye-sensitized solar cell developed by Graetzel et al. in Switzerland has attracted attention as a new type of solar cell. As a solar cell using organic materials, these solar cells have advantages such as high photoelectric conversion efficiency and lower manufacturing costs than silicon solar cells.

However, dye-sensitized solar cells are electrochemical cells, and therefore use organic electrolytic solutions and/or ionic liquids as electrolytes. In cases where organic electrolytic solutions are used, there is a problem in that electrical efficiency decreases due to volatilization and depletion during long-term use. Additionally, in cases where ionic liquids are used, while volatilization and depletion that occur during long-term use can be prevented, there are durability problems such as structural degradation caused by liquid leakage.

Therefore, research is being conducted regarding converting the electrolyte from a liquid to a gel or solid for the purpose of preventing the volatilization and liquid leakage of the electrolytic solution and ensuring the long-term stability and durability of the solar cell.

For example, Patent Document 1 describes an electrolyte for a photoelectric conversion element comprising (i) a lamellar clay mineral and/or an organically modified lamellar clay mineral and (ii) an ionic liquid (claim 1).

### PRIOR ART DOCUMENT

### Patent Document

Patent Document 1: Japanese Unexamined Patent Application Publication (translation of PCT application) No. 2007-531206

### SUMMARY OF THE INVENTION

### Problem to be Solved by the Invention

The present inventors discovered, as a result of investigating the photoelectric conversion element used in the electrolyte for a photoelectric conversion element described in Patent Document 1, that when heating at a temperature of about 85° C. for about 1,000 hours or longer, there are cases when the photoelectric conversion efficiency after heating declines.

On this point, Non-Patent Document 1 (Advanced Materials, Vol. 19, p. 1133-1137 (2007)) describes that heat resistance of a photoelectric conversion element increases when a salt compound formed from guanidine and thiocyanate is added to the electrolyte.

However, the present inventors discovered, as a result of investigating the salt compound described in Non-Patent Document 1, that very little enhancement of heat resistance is obtained by simply applying the technology of Non-Patent Document 1 to the electrolyte for a photoelectric conversion element described in Patent Document 1 (see Comparative Example 2).

Therefore, an object of the present invention is to provide an electrolyte for a photoelectric conversion element that can achieve superior heat resistance, and a photoelectric conversion element and a dye-sensitized solar cell using the electrolyte.

### Means to Solve the Problem

As a result of diligent research, the present inventors discovered that of electrolytes for a photoelectric conversion element including an organic salt compound containing a tertiary or quaternary cation, an electrolyte for a photoelectric conversion element including an organic salt compound containing a tertiary or quaternary cation and a thiocyanate anion achieves superior heat resistance, and thus arrived at the present invention.

Specifically, the present invention provides the following (i) to (vi).

(i) An electrolyte for a photoelectric conversion element including an organic salt compound (A) containing a tertiary or quaternary cation, wherein

at least an organic salt compound (a1) containing a tertiary or quaternary cation and a thiocyanate anion is used as the organic salt compound (A).

(ii) The electrolyte for a photoelectric conversion element described in (i), further including a lamellar clay mineral (B).

(iii) The electrolyte for a photoelectric conversion element described in (ii), wherein the lamellar clay mineral (B) contains an alkylsilyl group.

(iv) The electrolyte for a photoelectric conversion element described in any of (i) to (iii), wherein the organic salt compound (A) contains a cation that is expressed by the following Formula (1) or (2).

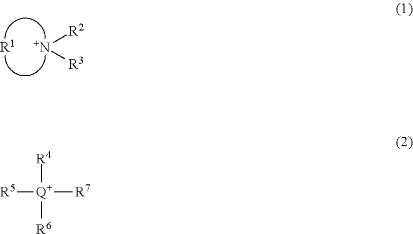

In Formula (1), R¹ is a hydrocarbon group having from 1 to 20 carbons that may contain a hetero atom, and may include a substituent having 1 to 20 carbons that may contain a hetero atom. R² and R³ are each independently a hydrocarbon group having from 1 to 20 carbons that may contain a hetero atom. However, the R³ moiety is absent if the nitrogen atom contains a double bond. In Formula (2), Q is a nitrogen, oxygen, phosphorus, or sulfur atom. R⁴, R⁵, R⁶, and R⁷ are each independently a hydrocarbon group having 1 to 8 carbons that may contain a hetero atom. However, the R⁷ moiety is absent if Q is an oxygen or a sulfur atom.

(v) A photoelectric conversion element including: a photoelectrode having a transparent conductive film and a metal oxide semiconductor porous film;

a counterelectrode disposed opposite the photoelectrode; and

an electrolyte layer disposed between the photoelectrode and the counterelectrode, wherein

the electrolyte layer is the electrolyte for a photoelectric conversion element described in any of (i) to (iv).

(vi) A dye-sensitized solar cell including the photoelectrode described in (v) carrying a photosensitized dye.

### Effect of the Invention

As described below, the present invention is useful for providing an electrolyte for a photoelectric conversion element that can achieve superior heat resistance, and a photoelectric conversion element and a dye-sensitized solar cell using the electrolyte.

Additionally, the dye-sensitized solar cell of the present invention is extremely useful, providing durability equivalent to that of an amorphous silicon solar cell due to having superior heat resistance.

### BRIEF DESCRIPTION OF THE DRAWINGS

FIG. 1 is a schematic cross-sectional view illustrating an example of a basic configuration of a photoelectric conversion element of the present invention.

FIG. 2 is a drawing illustrating a basic configuration of a solar cell of the present invention used in the Working Examples and the like.

### DETAILED DESCRIPTION

The present invention is explained in further detail below.

The electrolyte for a photoelectric conversion element of the present invention (hereinafter referred to simply as the “electrolyte of the present invention”) includes an organic salt compound (A) containing a tertiary or quaternary cation. Additionally, at least an organic salt compound (a1) containing a tertiary or quaternary cation and a thiocyanate anion is used as the organic salt compound (A).

Moreover, from the perspectives of being able to suppress volatilization and leakage and further enhancing heat resistance, the electrolyte of the present invention preferably includes a lamellar clay mineral (B).

Next, each constituent of the electrolyte of the present invention will be described in detail.

### Organic Salt Compound (A)

The organic salt compound (A) used in the electrolyte of the present invention is an organic salt compound containing a tertiary or quaternary cation.

Here, “tertiary cation” refers to a cation of a periodic table group 16 element (e.g. oxygen atom, sulfur atom, or the like) having a positive charge that does not include a hydrogen atom. “Quaternary cation” refers to a cation of a periodic table group 15 element (e.g. nitrogen atom, phosphorous atom, or the like) having a positive charge that does not include a hydrogen atom.

The organic salt compound (A) includes cations and, as counterions thereto, anions.

Specific examples of preferred cations include the cations expressed by Formula (1) or (2) below.

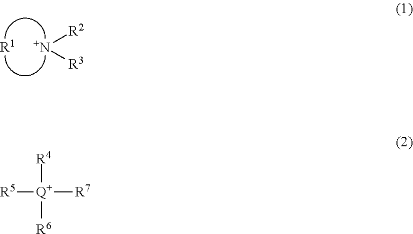

In Formula (1), R¹ is a hydrocarbon group having from 1 to 20 carbons that may contain a hetero atom, and may include a substituent having 1 to 20 carbons that may contain a hetero atom. R² and R³ are each independently a hydrocarbon group having from 1 to 20 carbons that may contain a hetero atom. However, the R³ moiety is absent if the nitrogen atom includes a double bond. In Formula (2), Q is a nitrogen, oxygen, phosphorus, or sulfur atom. R⁴, R⁵, R⁶, and R⁷ are each independently a hydrocarbon group having 1 to 8 carbons that may contain a hetero atom. However, the R⁷ moiety is absent if Q is an oxygen or a sulfur atom.

The hydrocarbon group in Formula (1) having from 1 to 20 carbons that may contain a hetero atom, R¹, preferably has a ring structure along with the nitrogen atom (ammonium ion) in Formula (1).

Next, preferable examples of the substituent, having from 1 to 20 carbons and that may contain a hetero atom that R¹ in Formula (1) may include, include alkyl groups having from 1 to 12 carbons (e.g. a methyl group, an ethyl group, a propyl group, a butyl group, a pentyl group, a hexyl group, a heptyl group, an octyl group, and the like), alkoxy groups having from 1 to 12 carbons (e.g. a methoxy group, an ethoxy group, an n-propoxy group, an iso-propoxy group, an n-butoxy group, a tert-butoxy group, a sec-butoxy group, an n-pentoxy group, an n-hexoxy group, a 1,2-dimethylbutoxy group, and the like), and alkylalkoxy groups having from 2 to 12 carbons (e.g. a methoxymethylene group (—CH₃OCH₃), a methoxyethylene group (—CH₂CH₂OCH₃), an n-propylene-iso-propoxy group (—CH₂CH₂CH₂OCH(CH₃)₂), a methylene-t-butoxy group (—CH₂—O—C(CH₃)₂, and the like). Additionally, R¹ in Formula (1) may include two or more of these substituents.

Preferable specific examples of the hydrocarbon group, having from 1 to 20 carbons and that may contain a hetero atom that R³ and R² in Formula (1) may include, include alkyl groups having from 1 to 12 carbons (e.g. a methyl group, an ethyl group, a propyl group, a butyl group, a pentyl group, a hexyl group, a heptyl group, an octyl group, and the like), alkoxy groups having from 1 to 12 carbons (e.g. a methoxy group, an ethoxy group, an n-propoxy group, an iso-propoxy group, an n-butoxy group, a tert-butoxy group, a sec-butoxy group, an n-pentoxy group, an n-hexoxy group, a 1,2-dimethylbutoxy group, and the like), alkylalkoxy groups having from 2 to 12 carbons (e.g. a methoxymethylene group (—CH₃OCH₃), a methoxyethylene group (—CH₂CH₂OCH₃), an n-propylene-iso-propoxy group (—CH₂CH₂CH₂OCH(CH₃)₂), a methylene-t-butoxy group (—CH₂—O—C(CH₃)₂, and the like), and the like.

Additionally, preferable specific examples of the hydrocarbon group, having from 1 to 8 carbons and that may contain a hetero atom, R⁷, R⁶, R⁵, and R⁴ in Formula (2) include alkyl groups having from 1 to 8 carbons (e.g. a methyl group, an ethyl group, a propyl group, a butyl group, a pentyl group, a hexyl group, a heptyl group, an octyl group, and the like), alkoxy groups having from 1 to 8 carbons (e.g. a methoxy group, an ethoxy group, an n-propoxy group, an iso-propoxy group, an n-butoxy group, a tert-butoxy group, a sec-butoxy group, an n-pentoxy group, an n-hexoxy group, a 1,2-dimethylbutoxy group, and the like), alkylalkoxy groups having from 2 to 8 carbons (e.g. a methoxymethylene group (—CH₃OCH₃), a methoxyethylene group (—CH₂CH₂OCH₃), an n-propylene-iso-propoxy group (—CH₂CH₂CH₂OCH(CH₃)₂), a methylene-t-butoxy group (—CH₂—O—C(CH₃)₂, and the like), and the like.

Examples of the cations expressed by Formula (1) include imidazolium ions, pyridinium ions, pyrrolidinium ions, piperidinium ions, and the like.

Specific examples of preferred cations include the cations expressed by any of Formulas (3) to (6) below.

Of these, the cations expressed by the following Formulas (3) and (5) are preferable because the photoelectric conversion efficiency of the photoelectric conversion element using the electrolyte of the present invention (hereinafter also referred to as the “photoelectric conversion element of the present invention”) tends to be better.

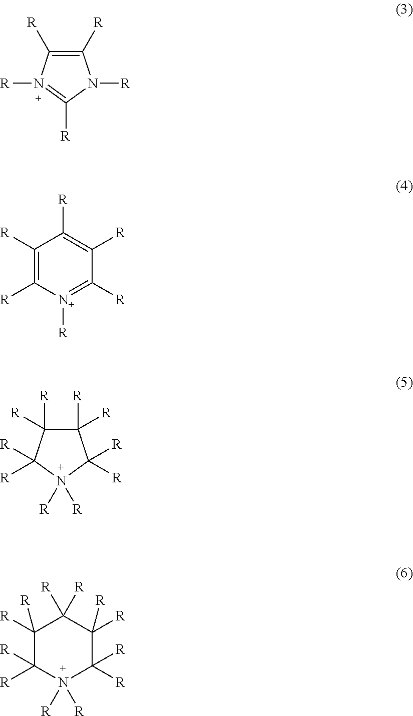

In Formulas (3) to (6), each R is independently a hydrocarbon group having from 1 to 20 carbons that may include a hetero atom.

Further specific examples of preferable cations include the following:

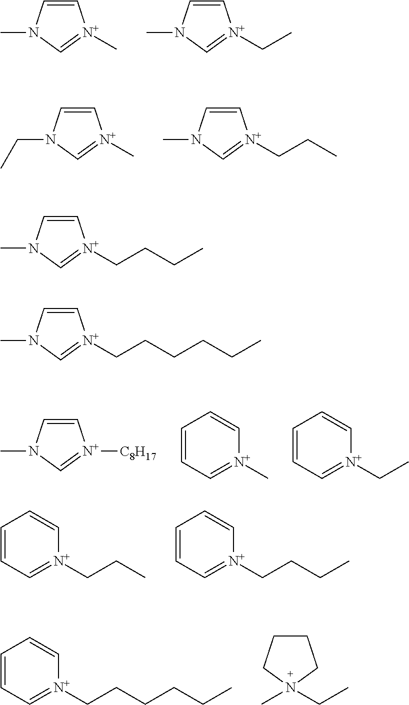

Examples of the cations of Formula (2) include organic cations such as ammonium ions, sulfonium ions, phosphonium ions, oxonium ions, and the like.

Specific examples of preferable cations are listed below.

Of these, aliphatic quaternary ammonium ions are preferable because the photoelectric conversion efficiency of the photoelectric conversion element of the present invention tends to be better.

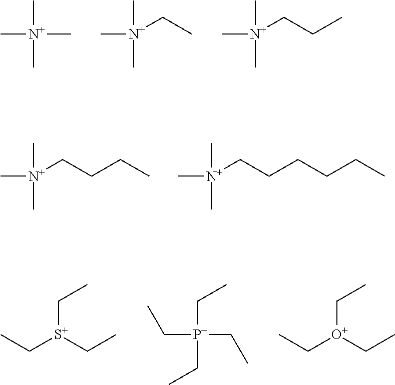

On the other hand, specific examples of preferably anions contained in the organic salt compound (A) include I⁻, Br⁻, AlCl₄⁻, Al₂Cl₇⁻, NO₃⁻, BF₄⁻, PF₆⁻, CH₃COO⁻, CF₃COO⁻, CF₃SO₃⁻, (CN)₄B⁻, SCN⁻, (CF₃SO₂)₂N⁻, (CN)₂N⁻, (CF₃SO₂)₃C⁻, (CN)₃C⁻, ASF₆⁻, SbF₆⁻, F(HF)ₙ⁻, CF₃CF₂CF₂CF₂SO₃⁻, (CF₃CF₂SO₂)₂N⁻, CF₃CF₂CF₂COO⁻, and the like.

In the present invention, at least an organic salt compound (a1) containing a tertiary or quaternary cation and a thiocyanate anion (SCN⁻) is used as the organic salt compound (A).

Examples of the organic salt compound (a1) include combinations of the cations and the thiocyanate anion described above. One of these may be used alone, or two or more may be used in combination.

Of these, an organic salt compound containing imidazolium ions and pyrrolidinium ions as the cation is preferable.

Additionally, a synthesis method of the organic salt compound (a1) is not particularly limited, and various types of organic salt compounds obtained by combining the cations and the thiocyanate anion described above can be synthesized by a conventionally known method.

Examples of synthetic products that can be used as the organic salt compound (a1) include N-methyl-N-butylpyrrolidinium thiocyanate, N-methyl-N-ethylpyrrolidinium thiocyanate, and the like. Additionally, commercially available products that can be used as the organic salt compound (a1) include N-methyl-3-ethylimidazolium thiocyanate (manufactured by Sigma-Aldrich Co. LLC.), N-ethyl-3-methylimidazolium thiocyanate (manufactured by Merck), N-methyl-3-butylimidazolium thiocyanate (manufactured by BASF), and the like.

In the present invention, an electrolyte for a photoelectric conversion element having superior heat resistance is obtained by including such an organic salt compound (a1) as the organic salt compound (A).

Reasons why superior heat resistance is achieved are not entirely clear, however, the following reasons are conceivable.

In cases where a metal complex is used wherein a thiocyanate anion (including linked isomer isothiocyanate anions; the definition of this paragraph applies hereinafter) is coordinated as the dye carried in the photoelectrode constituting the photoelectric conversion element, a cause of the decline in photoelectric conversion efficiency due to heating of the photoelectric conversion element is thought to be that the coordination of the thiocyanate anion is de-bonded due to the heating and an iodide ion, pyridine, or the like in the electrolyte is coordinated at that location.

In contrast, it is thought that by adding the organic salt compound containing the thiocyanate anion to the system, even if the coordination of the thiocyanate anion de-bonds from the metal complex (dye), coordination of the thiocyanate anion contained in the organic salt compound is possible and, thus, the functions of the dye, specifically the functions of absorbing light and emitting electrons, could be maintained.

Note that in cases where an organic salt compound containing a primary or secondary cation is used, the decline in photoelectric conversion efficiency due to heating cannot be suppressed, and initial photoelectric conversion efficiency is also low. It is thought that this is a result of the electrolyte becoming acidic due to the presence of hydrogen atoms (hydrogen ions).

In the present invention, a content of the organic salt compound (a1) is preferably from 1 to 45 mass %, and more preferably from 5 to 35 mass % of a total mass of the electrolyte of the present invention. If the content is within this range, the photoelectric conversion efficiency of the photoelectric conversion element of the present invention will be better.

On the other hand, in the present invention, as necessary, another organic salt compound (hereinafter referred to as the “organic salt compound (a2)) may be used in addition to the organic salt compound (a1) as the organic salt compound (A).

Examples of the organic salt compound (a2) include combinations of the cations and the anions described above (with the exception of the thiocyanate anion). One of these may be used alone, or two or more may be used in combination.

Of these, the organic salt compound preferably contains imidazolium ions and pyrrolidinium ions as the cations, and iodide ions (I⁻) and tetracyano boron ions ((CN)₄B⁻) as the anions.

Additionally, a synthesis method of the organic salt compound (a2) is not particularly limited, and various types of organic salt compounds obtained by combining the cations and the anions described above can be synthesized by a conventionally known method.

Examples of the organic salt compound (a2) include synthetic products such as N-methyl-3-methyl imidazolium iodide, N-methyl-3-ethyl imidazolium iodide, N-methyl-3-pentyl imidazolium iodide, N-methyl-3-hexyl imidazolium iodide, N-((2-methoxyethoxy)ethyl)-3-((2-methoxyethoxy)ethyl)imidazolium iodide, and the like; and commercially available products such as N-methyl-3-propyl imidazolium iodide (manufactured by Tokyo Chemical Industry Co., Ltd.), N-methyl-3-butyl imidazolium iodide (manufactured by Tokyo Chemical Industry Co., Ltd.), N-methyl-N-methyl-pyrrolidinium iodide (manufactured by Sigma-Aldrich Co. LLC.), N-methyl-3-ethylimidazolium tetracyanoborate (manufactured by Merck), and the like.

In the present invention, a content of the organic salt compound (a2), when optionally included, is preferably from 45 to 95 mass %, and more preferably from 55 to 95 mass % of a total mass of the electrolyte of the present invention. If the content is within this range, the photoelectric conversion efficiency of the photoelectric conversion element of the present invention will be better.

Additionally, in the present invention, a total content of the organic salt compound (a1) and the organic salt compound (a2), in other words, a content of the organic salt compound (A), is preferably from 65 to 95 mass % and more preferably from 75 to 95 mass % of the total mass of the electrolyte of the present invention; and a ratio (organic salt compound (a1)/organic salt compound (a2)) is preferably from 0.02 to 0.70 and more preferably from 0.15 to 0.55.

Furthermore, in the present invention, from the perspective of the preparation of the electrolyte of the present invention, the organic salt compound (a1) and/or the organic salt compound (a2) is preferably a liquid ionic liquid at room temperature. By “liquid”, it is meant that when two or more of the organic salt compound (a1) and the organic salt compound (a2) are combined and used, the mixture thereof is in a liquid state.

Additionally, for the same reason, in the present invention, a conventional ionic liquid that is not the organic salt compound (A) can be included. For example, a quaternary ammonium salt, an imidazolium salt, a pyridinium salt, a pyrrolidinium salt, a piperidinium salt, and the like described in, “Ionic Liquids: The Front and Future of Material Development”, Hiroyuki OHNO, CMC Publishing, 2003; “Functional Creation and Applications of Ionic Liquids”, Hiroyuki OHNO, NTS Publishing, 2004; and the like can be used.

### Lamellar Clay Mineral (B)

The lamellar clay mineral (B) that is optionally included in the electrolyte of the present invention is not particularly limited, and is preferably a phyllosilicate having a silicic acid tetrahedron bonded in a bi-dimensional sheet-like form. Examples thereof include smectite-based clay minerals such as montmorillonite, saponite, beidellite, nontronite, hectorite, stevensite, and the like; vermiculite-based clay minerals such as vermiculite and the like; natural or synthetic clay minerals such as muscovite, phlogopite, mica, and the like; and the like. One of these may be used alone, or two or more may be used in combination.

Of these, smectite-based clay minerals that expand in water and have cation exchange capacity or expanding mica is preferable.

Here, a cation exchange capacity of the lamellar clay mineral is preferably from 10 to 300 milliequivalents/100 g.

Preferable examples of commercially available product that can be used as such a lamellar clay mineral (B) include natural montmorillonite (trade name: Kunipia F, manufactured by Kunimine Industries Co., Ltd.; average particle size: 0.1 to 1 μm), synthetic smectite (trade name: Sumecton SA, manufactured by Kunimine Industries Co., Ltd.; average particle size: 20 nm), synthetic expanding mica (trade name: Somasif ME-100, manufactured by Co-op Chemical Co., Ltd.; average particle size: 1 to 3 μm); synthetic smectite (trade name: Lucentite SWN, manufactured by Co-op Chemical Co., Ltd.; average particle size: 0.02 μm); and synthetic smectite (trade name: Lucentite SWF, manufactured by Co-op Chemical Co., Ltd.; average particle size: 0.02 μm).

In the present invention, an organically modified lamellar clay mineral can be used as the lamellar clay mineral (B).

The organically modified lamellar clay mineral can be obtained by regular inter-layer cation-exchanging and, for example, can be obtained by adding organic onium ions to a water-based slurry of the lamellar clay mineral and mixing in order to induce a reaction.

Here, the “organic onium ions” are ions that are generated from an organic onium compound produced by coordinate bonding a proton or another cationic reagent, or the like to a lone electron pair in a compound including an element such as oxygen, sulfur, nitrogen, and the like that has a lone electron pair.

Additionally, conditions for organically modifying using the organic onium ions are not particularly limited, and the reaction is preferably induced using an amount of the organic onium ions 0.3 to 2.0 times, and more preferably induced using an amount of the organic onium ions 0.5 to 1.5 times the cation exchange capacity of the lamellar clay mineral, and the reaction is preferably induced at a temperature of from 10 to 95° C.

Examples of the organic onium ions include ammonium ions, phosphonium ions, oxonium ions, sulfonium ions, and the like.

Of these, ammonium ions are the most common, and specific examples thereof include aliphatic ammonium ions, pyridinium ions, quinolinium ions, imidazolium ions, pyrrolidinium ions, piperidinium ions, betaines, lecithin, cation dyes (pigments), and the like.

Additionally, the aliphatic ammonium ions expressed by Formulas (1) and (II) below are preferable, and examples thereof include hydroxypolyoxyethylene trialkylammonium, hydroxypolyoxypropylene trialkylammonium, di(hydroxypolyoxyethylene)dialkylammonium, di(hydroxypolyoxypropylene)dialkylammonium, dimethyldioctylammonium, dimethyldidodecylammonium, methylethyldioctylammonium, methylethyldioctylammonium, methyltrioctylammonium, methyltridodecylammonium, benzylmethyldioctylammonium, benzylmethyldidodecylammonium, benzylethyldioctylammonium, benzylethyldioctylammonium, benzyltrioctylammonium, benzyltridodecylammonium, and the like.

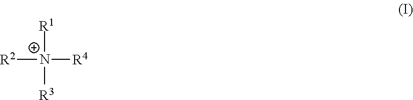

In Formula (1), R¹ is a hydrocarbon group having from 1 to 30 carbons; R² and R³ are each independently a polyoxyethylene group (—(CH₂CH₂O)ₙ—H), a polyoxypropylene group (—(CH₂CH(CH₂)O)ₙ—H, —(CH₂CH₂CH₂O)ₙ—H), or a hydrocarbon group having from 1 to 10 carbons; and R⁴ is a polyoxyethylene group (—(CH₂CH₂O)ₙ—H) or a polyoxypropylene group (—(CH₂CH(CH₂)O)ₙ—H, —(CH₂CH₂CH₂O)ₙ—H). Moreover, n is an integer from 1 to 50.

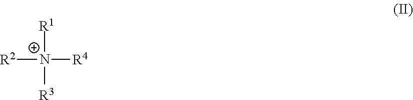

In Formula (II), R¹ is a methyl group or a benzyl group; R² is a hydrocarbon group having from 1 to 3 carbons or a hydrocarbon group having from 6 to 15 carbons; and R³ and R⁴ are each independently a hydrocarbon group having from 6 to 15 carbons.

Examples of commercially available products that can be used as such an organically modified lamellar clay mineral include S-BEN NX, S-BEN WX, Organite, and Organite D (all manufactured by Hojun Yoko K.K.); Lucentite SEN, Lucentite SPN, Lucentite SAN, Lucentite STN, Somasif MAE, Somasif MEE, Somasif MPE, and Somasif MTE (all manufactured by Co-op Chemical Co., Ltd.); and the like.

In the present invention, from the perspective of obtaining excellent moisture resistance of the photoelectric conversion element of the present invention the lamellar clay mineral (B) preferably contains an alkylsilyl group.

Examples of the lamellar clay mineral (B) containing an alkylsilyl group include reactant products of the lamellar clay minerals described above (hereinafter also referred to as “lamellar clay mineral (b1)”) and an organosilane compound (b2) described below; commercially available products described below; and the like.

Organosilane compound (b2)

Examples of the organosilane compound (b2) used in the preparation of the lamellar clay mineral (B) include products expressed by Formula (7) below.

R⁸ₙ—Si—R⁹₄₋ₙ (7)

In Formula (7), R⁸ is a monovalent hydrocarbon group that may be branched, having from 1 to 25 carbons, and may contain a hetero atom. R⁹ is a hydrolyzable group, and n is an integer from 1 to 3. When n is 2 or 3, the plurality of R⁸ moieties may be the same or different, and when n is 1 or 2, the plurality of R⁹ moieties may be the same or different.

Examples of the monovalent hydrocarbon group that may be branched, having from 1 to 25 carbons in Formula (7), R⁸, include methyl groups, ethyl groups, propyl groups, isopropyl groups, n-butyl groups, isobutyl groups, sec-butyl groups, tert-butyl groups, n-pentyl groups, isopentyl groups, neopentyl groups, tert-pentyl groups, 1-methylbutyl groups, 2-methylbutyl groups, 1,2-dimethylpropyl groups, hexyl groups, heptyl groups, octyl groups, nonyl groups, decyl groups, dodecyl groups, tridecyl groups, tetradecyl groups, hexadecyl groups, octadecyl groups, cyclohexyl groups, vinyl groups, allyl groups, phenyl groups, tolyl groups, styryl groups, α-methylstyryl groups, and the like; functional groups (e.g. chloromethyl groups, chloropropyl groups, trifluoropropyl groups, and the like) wherein part or all of the hydrogen atoms bonded to the carbon atoms of the groups described above are substituted with a halogen atom (e.g. chlorine or the like); and the like.

Moreover, examples of the hydrolyzable group in Formula (7), R⁹, include alkoxy groups, acyl groups, halogen groups, and the like.

Examples of the compound expressed by Formula (7) include methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, n-butyltrimethoxysilane, n-butyltriethoxysilane, n-pentyltrimethoxysilane, n-pentyltriethoxysilane, cyclohexyltrimethoxysilane, phenyltrimethoxysilane, hexyltrimethoxysilane, octyltriethoxysilane, nonyltriethoxysilane, decyltriethoxysilane, dodecyltriethoxysilane, tridecyltriethoxysilane, tetradecyltriethoxysilane, pentadecyltriethoxysilane, dimethyldimethoxysilane, dimethyldiethoxysilane, diethyldimethoxysilane, diethyldiethoxysilane, di-n-propyldimethoxysilane, di-i-propyldimethoxysilane, di-n-butyldimethoxysilane, n-pentyl.methyldimethoxysilane, cyclohexyl.methyldiethoxysilane, phenyl.methyldimethoxysilane, di-n-pentyldimethoxysilane, di-n-hexyldimethoxysilane, di-n-heptyldimethoxysilane, di-n-octyldimethoxysilane, dicyclohexyldimethoxysilane, diphenyldimethoxysilane, trimethylmethoxysilane, triethylmethoxysilane, tri-n-propylmethoxysilane, tri-i-propylmethoxysilane, tri-n-butylmethoxysilane, tri-n-pentylmethoxysilane, tri-cyclohexylmethoxysilane, triphenylmethoxysilane, tri-n-hexylmethoxysilane, tri-n-heptylmethoxysilane, tri-n-octylmethoxysilane, tricyclohexylmethoxysilane, triphenylmethoxysilane, tridecylmethoxysilane, vinyltrichlorosilane, vinyltrimethoxysilane, vinyltriethoxysilane, vinyl-tris(methoxyethoxy)silane, vinyltriisopropoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-acryloxypropyltrimethoxysilane, 3-mercaptopropylmethyldimethoxysilane, 3-mercaptopropyltrimethoxysilane, bis(triethoxysilylpropyl) disulfide, bis(triethoxysilylpropyl)tetrasulfide, methyltrichlorosilane, methyldichlorosilane, dimethyldichlorosilane, trimethylchlorosilane, phenyltrichlorosilane, diphenyldichlorosilane, octyldimethylchlorosilane, trifluoropropyltrichlorosilane, cyclohexylmethyldimethoxysilane, trifluoropropyltrimethoxysilane, triphenylsilanol, hexamethyldisilazane, methyltriphenoxysilane, and the like. One of these may be used alone, or two or more may be used in combination.

Of these, from the perspective of being able to suppress hygroscopicity of the electrolyte in a device, methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, n-butyltrimethoxysilane, n-butyltriethoxysilane, n-pentyltrimethoxysilane, n-pentyltriethoxysilane, cyclohexyltrimethoxysilane, phenytrimethoxysilane, hexyltrimethoxysilane, octyltriethoxysilane, nonyltriethoxysilane, dimethyldimethoxysilane, dimethyldiethoxysilane, diethyldimethoxysilane, diethyldiethoxysilane, di-n-propyldimethoxysilane, di-i-propyldimethoxysilane, di-n-butyldimethoxysilane, n-pentyl.methyldimethoxysilane, cyclohexyl.methyldiethoxysilane, phenyl.methyldimethoxysilane, diphenyldimethoxysilane, trimethylmethoxysilane, trimethylethoxysilane, triethylmethoxysilane, tri-n-propylmethoxysilane, tri-i-propylmethoxysilane, vinyltrimethoxysilane, vinyltriethoxysilane, 3-mercaptopropyltrimethoxysilane, bis(triethoxysilylpropyl) disulfide, bis(triethoxysilylpropyl)tetrasulfide, cyclohexylmethyldimethoxysilane, trifluoropropyltrimethoxysilane, and hexamethyldisilazane are preferable.

Additionally, examples that can be used as the organosilane compound (b2) include condensation products of the compounds expressed by Formula (7) including organopolysiloxane such as dimethylpolysiloxane, methylphenylpolysiloxane, methylhydrogensiloxane, and the like.

Furthermore, organodisilazanes such as hexamethyldisilazane, divinyltetramethyldisilazane, and the like can be used as the organosilane compound (b2).

In the present invention, the reaction of the lamellar clay mineral (b1) and the organosilane compound (b2) is not particularly limited, and the lamellar clay mineral (B) containing an alkylsilyl group can be prepared by stirring these in an organic solvent such as methanol or the like at a temperature from about 0 to 250° C., thereby reacting the hydroxy group contained in the lamellar clay mineral (b1) and the hydrolyzable group contained in the organosilane compound (b2).

“The hydroxy group contained in the lamellar clay mineral (b1)” refers to the hydroxy group contained in the crystalline layer (in most cases, the end face) of a conventional lamellar clay mineral such as montmorillonite, smectite, or the like. However, in the reaction described above, all of the hydroxy groups contained in the lamellar clay mineral (b1) need not be substituted by alkylsilyl groups.

On the other hand, in the present invention, examples of products that can be preferably used as the lamellar clay mineral (B) containing an alkylsilyl group include commercially available products such as silane-treated montmorillonite treated with alkyltrialkoxysilane (Bengel SH, manufactured by Hojun Yoko K.K.), silane-treated organic bentonite treated with quaternary ammonium and alkyltrialkoxysilane (manufactured by Hojun Yoko K.K.), and the like.

By including the lamellar clay mineral (B) containing an alkylsilyl group described above, a photoelectric conversion element having superior moisture resistance can be formed.

While the reasons why this is so are not specifically clear, it is thought that the lamellar clay mineral (B) containing the alkylsilyl group prevents the intrusion of atmospheric water vapor due to it being hydrophobized to a greater degree than conventional lamellar clay minerals.

In the present invention, a content of the lamellar clay mineral (B), when optionally included and indicated as a content of inorganic matter, is preferably from 1 to 250 parts by mass, and more preferably from 2 to 150 parts by mass per 100 parts by mass of the organic salt compound (A).

Here, “indicated as a content of inorganic matter” takes into account the content of the organically modified lamellar clay mineral, and, when using the organically modified lamellar clay mineral, refers to the mass excluding the inter-layer cations, specifically the organic onium ions. Note that lamellar clay mineral that is not organically modified is an inorganic material including inter-layer cations (e.g. Na⁺, K⁺, Li⁺ and the like). Therefore, the value of the content indicated as inorganic matter and the content indicated as the entire product are the same.

A redox couple can be added to the electrolyte of the present invention in order to enhance the photoelectric conversion efficiency of the photoelectric conversion element of the present invention.

Any conventional product commonly used for, or that can be used for, dye-sensitized solar cells may be used as the redox couple so long as the object of the present invention is not impaired.

For example, iodine/iodide ion pairs, bromine/bromide ion pairs, and the like can be used. Specific examples thereof include iodine/iodide ion pairs such as metal iodides of iodine and LiI, NaI, KI, or the like, iodide salts of iodine and a quaternary imidazolium compound, iodide salts of iodine and a quaternary pyridinium compound, iodide salts of iodine and a tetralkylammonium compound, and the like; bromine/bromide ion pairs such as metal bromides of bromine and LiBr, NaBr, KBr, and the like, bromide salts of bromine and a quaternary imidazolium compound, bromide salts of bromine and a quaternary pyridinium compound, bromide salts of bromine and a tetralkylammonium compound, and the like; metal complexes such as ferrocyanate-ferricyanate, ferrocene-ferricinium salt, and the like; sulfur compounds of a disulfide compound and a mercapto compound; hydroquinone; quinone; and the like. One of these may be used alone, or two or more may be used in combination.

Of these, iodine/iodide ion pairs and bromine/bromide ion pairs are preferable.

Additionally, an inorganic salt and/or an organic salt can be added to the electrolyte of the present invention in order to enhance short current of the photoelectric conversion element of the present invention.

Examples of the inorganic salt and/or organic salt include alkali metals, alkali earth metal salts, and the like, such as lithium iodide, sodium iodide, potassium iodide, magnesium iodide, calcium iodide, lithium trifluoroacetate, sodium trifluoroacetate, lithium thiocyanate, lithium tetrafluoroborate, lithium hexaphosphate, lithium perchlorate, lithium trifluoromethanesulfonate, lithium bis(trifluoromethanesulphonyl)imide, and the like. One of these may be used alone, or two or more may be used in combination.

An added amount of the inorganic salt and/or organic salt is not particularly limited and may be a conventional amount so long as the object of the present invention is not inhibited.

Additionally, a pyridine and/or a benzimidazole can be added to the electrolyte of the present invention in order to enhance the open voltage of the photoelectric conversion element of the present invention.

Specific examples include alkylpyridines such as methylpyridine, ethylpyridine, propylpyridine, butylpyridine, and the like; alkylimidazoles such as methylimidazole, ethylimidazole, propylimidazole, and the like; alkylbenzimidazoles such as methylbenzimidazole, ethylbenzimidazole, butylbenzimidazole, propylbenzimidazole, and the like; and the like. One of these may be used or alone, or two or more may be used in combination.

An added amount of the pyridine and/or the benzimidazole is not particularly limited and can be a conventional amount, so long as the object of the present invention is not inhibited.

An organic solvent may be added to the electrolyte of the present invention, and examples thereof include carbonate esters such as ethylene carbonate, propylene carbonate, and the like; ethers such as ethylene glycol dialkyl ether, propylene glycol dialkyl ether, and the like; alcohols such as ethylene glycol monoalkyl ether, propylene glycol monoalkyl ether, and the like; polyhydric alcohols such as ethylene glycol, propylene glycol, and the like; nitriles such as acetonitrile, propionitrile, methoxypropionitrile, cyanoethyl ether, glutaronitrile, valeronitrile, and the like; lactones such as γ-butyrolactone and the like; amides such as dimethylformamide, N-methylpyrrolidone, and the like; aprotic polar solvents such as dimethyl sulfoxide, sulfolane, and the like; and the like. One of these may be used alone, or two or more may be used in combination.

An added amount of the organic solvent is not particularly limited and can be a conventional amount so long as the object of the present invention is not inhibited.

A manufacturing method of the electrolyte of the present invention is not particularly limited and can, for example, be manufactured by mixing the organic salt compound (A) and the optionally included lamellar clay mineral (B), and then thoroughly mixing and uniformly dispersing (kneading) using a ball mill, sand mill, pigment disperser, grinder, ultrasonic disperser, homogenizer, planetary mixer, Hobart mixer, roll, kneader, or the like at room temperature or under heat (e.g. from 40 to 150° C.)

Here, as necessary, an organic solution (e.g. toluene or the like) can be mixed in with the mixture described above and, after the mixing, the organic solution may be removed using vacuum distillation.

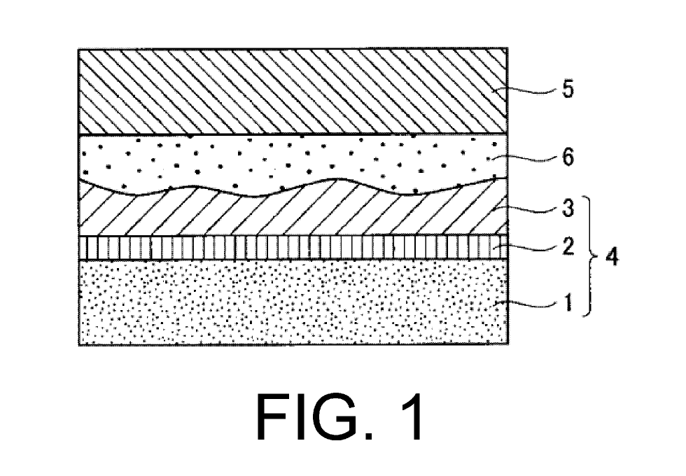

Next, the photoelectric conversion element and the dye-sensitized solar cell of the present invention will be described using FIG. 1. FIG. 1 is a schematic cross-sectional view illustrating an example of a basic configuration of a photoelectric conversion element of the present invention.

The photoelectric conversion element of the present invention includes a photoelectrode having a transparent conductive film and a metal oxide semiconductor porous film, a counterelectrode disposed so as to oppose the photoelectrode, and an electrolyte layer provided between the photoelectrode and the counterelectrode.

### Photoelectrode

As illustrated in FIG. 1, the photoelectrode is, for example, constituted by a transparent plate 1, a transparent conductive film 2, and an oxide semiconductor porous film 3.

Here, the transparent plate 1 preferably has excellent optical transparency, and specific examples include, in addition to glass plates, resin plates (films) such as polystyrene, polyethylene, polypropylene, polyethylene terephthalate, polyethylene naphthalate, polycarbonate, polyphenylene sulfide, cyclic olefin polymer, polyether sulfone, polysulfone, polyetherimide, polyarylate, triacetylcellulose, methyl polymethacrylate, and the like.

Additionally, specific examples of the transparent conductive film 2 include conductive metal oxides such as tin oxide doped with antimony or fluorine, zinc oxide doped with aluminum or gallium, indium oxide doped with tin, and the like.

Moreover, a thickness of the transparent conductive film 2 is preferably from about 0.01 to 1.0 μm.

Furthermore, the method for providing the transparent conductive film 2 is not particularly limited, and examples thereof include coating methods, sputtering methods, vacuum deposition methods, spray pyrolysis methods, chemical vapor deposition (CVD) methods, sol-gel methods, and the like.

Next, the oxide semiconductor porous film 3 is obtained by applying a dispersion of oxide semiconductor particles on the transparent conductive film 2.

Specific examples of the oxide semiconductor particles include titanium oxide, tin oxide, zinc oxide, tungsten oxide, zirconium oxide, hafnium oxide, strontium oxide, vanadium oxide, niobium oxide, and the like. One of these may be used alone, or two or more may be used in combination.

The dispersion is obtained by mixing the oxide semiconductor particles and a carrier medium using a disperser such as a sand mill, bead mill, ball mill, three-roll mill, colloid mill, ultrasonic homogenizer, Henschel mixer, jet mill, or the like.

Additionally, the dispersion, after being obtained by mixing using the disperser and immediately prior to use (application), is preferably subjected to ultrasonic treatment using an ultrasonic homogenizer or the like. By performing the ultrasonic treatment immediately prior to use, the photoelectric conversion efficiency of the photoelectric conversion element of the present invention will be better. Reasons for this are thought to be that the filling of the oxide semiconductor porous film, formed using the dispersion that has been subjected to ultrasonic treatment immediately prior to use, with the electrolyte of the present invention including the organic salt compound (A) is facilitated and the adsorption capacity of the dye is increased.

Furthermore, acetyl acetone, hydrochloric acid, nitric acid, surfactants, chelating agents, and the like may be added to the dispersion in order to prevent the oxide semiconductor particles in the dispersion from re-aggregating; and a polymeric or cellulose thickening agent such as polyethylene oxide, polyvinylalcohol, and the like may be added to increase the viscosity of the dispersion.

Examples of commercially available products that can be used as the dispersion include titanium oxide pastes SP100 and SP200 (both manufactured by Showa Denko K.K.), titanium dioxide fine particle Ti-Nanoxide T (manufactured by Solaronix S.A.), Ti-Nanoxide D (manufactured by Solaronix S.A.), Ti-Nanoxide T/SP (manufactured by Solaronix S.A.), Ti-Nanoxide D/SP (manufactured by Solaronix S.A.), titania coating paste PECC01 (manufactured by Peccell Technologies), titania particle pastes PST-18NR and PST-400C (both manufactured by Nikki Chemical Co., Ltd.), and the like.

A conventional wet film forming method, for example, can be used as the method for applying the dispersion on the transparent conductive film.

Specific examples of the wet film forming method include screen printing methods, ink jet printing methods, roll coating methods, doctor blade methods, spincoating methods, spraying methods, and the like.

Additionally, after applying the dispersion on the transparent conductive film, a heat treatment, chemical treatment, plasma, or ozone treatment is preferably performed in order to enhance electric contact between the particles, enhance adhesion with the transparent conductive film, and enhance film strength.

A temperature of the heat treatment is preferably from 40° C. to 700° C. and more preferably from 40° C. to 650° C. Additionally, a duration of the heat treatment is not particularly limited, but is normally from about 10 seconds to 24 hours.

Specific examples of the chemical treatment include chemical plating using a titanium tetrachloride aqueous solution, chemisorption using a carboxylic acid derivative, electrochemical plating using a titanium trichloride aqueous solution, and the like.

### Counterelectrode

As illustrated in FIG. 1, the counterelectrode is an electrode 5, disposed opposite a photoelectrode 4. For example, a metal plate, or a glass plate or a resin plate having a conductive film on a surface thereof, can be used.

Examples of metals that can be used as the metal plate include platinum, gold, silver, copper, aluminum, indium, titanium, and the like. Examples of resin plates that can be used include, in addition to the plate (film) exemplified by the transparent plate 1 that constitutes the photoelectrode 4, common resin plates that are non-transparent or have limited transparency.

Additionally, examples of the conductive film provided on the surface include conductive metal oxides and the like such as metals such as platinum, gold, silver, copper, aluminum, indium, titanium, and the like; carbon; tin oxide; tin oxides doped with antimony or fluorine; zinc oxide; zinc oxides doped with aluminum or gallium; indium oxides doped with tin; and the like. A thickness and a forming method of the conductive film are the same as for the transparent conductive film 2 that constitutes the photoelectrode 4.

In the present invention, an electrode having a conductive polymeric film formed on a plate or a conductive polymeric film electrode can be used as a counterelectrode 5.

Specific examples of the conductive polymer include polythiophene, polypyrrole, polyaniline, and the like.

Examples of a method for forming the conductive polymeric film on the plate include a method in which a conductive polymeric film from a polymeric dispersion is formed on a plate using a conventionally known wet film forming method such as a dipping method or a spin coating method.

Examples of products that can be used as the conductive polymeric dispersion include a polyaniline dispersion described in Japanese Unexamined Patent Application No. 2006-169291, commercially available products such as a polythiophene derivative aqueous dispersion (Baytron P, manufactured by Bayer), Aquasave (manufactured by Mitsubishi Rayon, polyaniline derivative aqueous solution), and the like.

Additionally, when the plate is the conductive plate, in addition to the method described above, the conductive polymeric film can also be formed on the plate via an electrolysis polymerization method. The conductive polymeric film electrode can use a self-standing film wherein the conductive polymeric film formed on the electrode by the electrolysis polymerization method is peeled from the electrode, or a self-standing film formed using a casting method, a spin coating method, or the like that is conventionally known as a wet film forming method for forming a film from a conductive polymeric dispersion. Here, for convenience, a mixture of a state in which conductive polymeric particles are dispersed throughout the vehicle and a state in which conductive polymers are dissolved in the vehicle is referred to as the “conductive polymeric dispersion.”

### Electrolyte

As illustrated in FIG. 1, the electrolyte layer is an electrolyte layer 6 that is provided between the photoelectrode 4 and the counterelectrode 5. The electrolyte of the present invention described above is used in the photoelectric conversion element of the present invention.

The photoelectric conversion element of the present invention can achieve superior heat resistance because the electrolyte of the present invention described above is used.

The dye-sensitized solar cell of the present invention is a type of photoelectric conversion element wherein the photoelectrode constituting the photoelectric conversion element of the present invention described above carries a photosensitized dye.

Here, the photosensitized dye is not particularly limited so long as it is a metal complex on which, of dyes that absorb light in the visible range or the infrared range, a thiocyanate anion (including linked isomer isothiocyanate anions) is coordinated.

Examples thereof that can be used include ruthenium complex dyes (see the following formula), iron complex dyes, osmium complex dyes, platinum complex dyes, iridium complex dyes, and the like on which a ligand having a bipyridine structure, a terpyridine structure, or the like is coordinated.

A method for applying the photosensitized dye is not particularly limited and can be applied by dissolving the dye described above in, for example, water or an alcohol, and then immersing (adsorbing) the oxide semiconductor porous film 3 in the dye solution or coating the dye solution on the oxide semiconductor porous film 3.

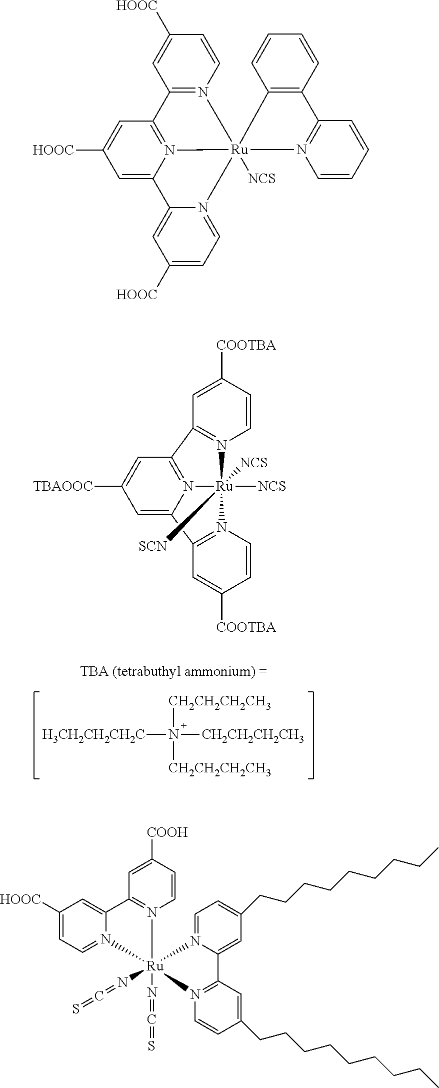

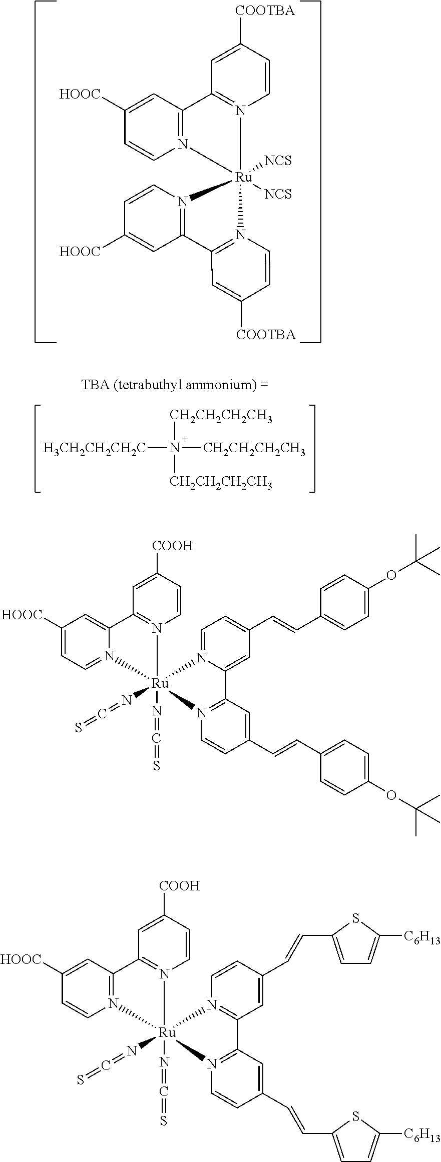

### EXAMPLES

The present invention will now be described in greater detail using the following examples, but is in no way limited to these examples.

### Working Examples 1 to 13 and Comparative Examples 1 to 5

### Preparation of the Electrolyte

An organic salt compound, shown in Table 1 below, was blended and mixed in a mixing container according to the composition ratios shown in Table 1 to prepare the electrolyte.

Specifically, according to the composition ratios shown in Table 1, lamellar clay mineral B1 and/or lamellar clay mineral B2 that were pre-expanded and dispersed in toluene were added to the organic salt compound a2 shown in Table 1 while stirring. Then, the mixture was stirred for three hours at room temperature.

Thereafter, the reaction solution was left to rest and the toluene solution was removed. Furthermore, the precipitate was washed with toluene and then dried to obtain a gel-like substance.

The organic salt compound a1 or the organic salt compound 1, iodine, and N-methylbenzimidazole shown in Table 1 were stirred and mixed with the obtained gel-like substance according to the composition ratios shown in Table 1.

### Fabrication of the Dye-Sensitized Solar Cell

A titanium oxide paste (Ti-Nanoxide D, manufactured by Solaronix) was coated on transparent conductive glass (FTO glass, surface resistance: 15 Ω/square, manufactured by Nippon Sheet Glass Co., Ltd.) and dried at room temperature, and thereafter was sintered for 30 minutes at a temperature of 450° C. Thereby, a photoelectrode having a titanium oxide porous film formed on transparent conductive glass was fabricated.

The fabricated photoelectrode was then immersed for four hours in a ruthenium complex dye (cis-(diisothiocyanate)-N,N′-bis(2,2′-bipyridyl-4,4′-dicarboxylic acid)ruthenium(II)complex) (Ruthenium 535-bis TBA, manufactured by Solaronix) butyl alcohol/acetonitrile solution (Specific volume: 1/1; Concentration: 3×10⁴ mol/L).

Thereafter, the product was washed using acetonitrile and dried in a dark location under a stream of nitrogen. Thus a photoelectrode carrying a photosensitized dye in a titanium oxide electrode of a photoelectrode was used as the photoelectrode.

The prepared electrolyte was applied on the photoelectrode carrying the photosensitized dye, and this and a platinum counterelectrode formed by forming a platinum film having a thickness of about 100 nm on a surface of a transparent conductive glass plate using a sputtering method (indium oxide doped with tin on a conductive face, sheet resistance: 8 Ω/square, manufactured by Nippon Sheet Glass Co., Ltd.) were bonded. When bonding, a thermal fusion bonding film was interposed between the photoelectrode and the platinum counterelectrode. Thermal fusion bonding was performed at 150° C. and a seal was formed between the electrodes. Thus, the dye-sensitized solar cell was obtained.

The photoelectric conversion efficiency, heat resistance, moisture resistance, and moist heat resistance of the obtained dye-sensitized solar cell were measured according to the methods described below and evaluated. The results are shown in Table 1.

### Photoelectric Conversion Efficiency

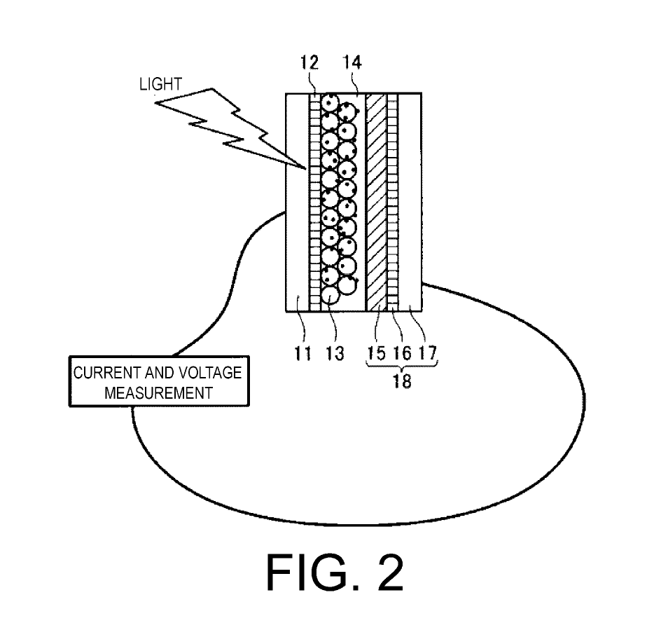

As illustrated in FIG. 2, a solar simulator is used as a light source, the photoelectrode side was irradiated with AM 1.5 artificial sunlight at a light intensity of 100 mW/cm², and the conversion efficiency was calculated using a current-voltage measuring device (Digital Source Meter 2400, manufactured by Keithley Instruments Inc.).

### Heat Resistance (Decline Ratio)

The dye-sensitized solar cell that was measured for photoelectric conversion efficiency was left for 1,000 hours at a temperature of 85° C. and, thereafter, was measured again for photoelectric conversion efficiency according to the same method described above. The decline ratio (post-heating photoelectric conversion efficiency/pre-heating photoelectric conversion efficiency) was calculated.

When the calculated results of the decline ratio of photoelectric conversion efficiency was 0.85 or greater, the heat resistance was evaluated as being superior.

### Moisture Resistance (Decline Ratio)

The dye-sensitized solar cell that was measured for photoelectric conversion efficiency was left for 1,000 hours at a temperature of 40° C. and an RH of 85% and, thereafter, was measured again for photoelectric conversion efficiency according to the same method described above. The decline ratio (post-humidifying photoelectric conversion efficiency/pre-humidifying photoelectric conversion efficiency) was calculated.

When the calculated results of the decline ratio of photoelectric conversion efficiency was 0.80 or greater, the moisture resistance was evaluated as being superior.

### Moist Heat Resistance (Decline Ratio)

The dye-sensitized solar cell that was measured for photoelectric conversion efficiency was left for 1,000 hours at a temperature of 85° C. and an RH of 85% and, thereafter, was measured again for photoelectric conversion efficiency according to the same method described above. The decline ratio (post-heating·post-humidifying photoelectric conversion efficiency/pre-heating·pre-humidifying photoelectric conversion efficiency) was calculated.

When the calculated results of the decline ratio of photoelectric conversion efficiency was 0.80 or greater, the moist heat resistance was evaluated as being superior.

TABLE 1

| | Working Examples | | | | | | | Comparative Examples | | | | |
|---|---|---|---|---|---|---|---|---|---|---|---|---|
| | 1 | 2 | 3 | 4 | 5 | 6 | 7 | 1 | 2 | 3 | 4 | 5 |
| Organic salt | 6.05 | 6.05 | 6.05 | 6.05 | | | | 6.05 | 6.05 | 6.05 | | |
| compound a2-1 | | | | | | | | | | | | |
| Organic salt | | | | | 2.69 | 2.69 | 2.69 | | | | 2.69 | 2.69 |
| compound a2-2 | | | | | | | | | | | | |
| Organic salt | | | | | 2.86 | 2.86 | 2.86 | | | | 2.86 | 2.86 |
| compound a2-3 | | | | | | | | | | | | |
| Organic salt | 1.35 | 1.69 | 2.03 | | 1.35 | 1.69 | | | | | | |
| compound a1-1 | | | | | | | | | | | | |
| Organic salt | | | | 1.58 | | | 1.58 | | | | | |
| compound a1-2 | | | | | | | | | | | | |
| Organic salt | | | | | | | | | 0.08 | 0.95 | | 0.95 |
| compound 1 | | | | | | | | | | | | |
| Iodine | 0.40 | 0.40 | 0.40 | 0.40 | 0.40 | 0.40 | 0.40 | 0.40 | 0.40 | 0.40 | 0.40 | 0.40 |
| N- | 0.38 | 0.38 | 0.38 | 0.38 | 0.38 | 0.38 | 0.38 | 0.38 | 0.38 | 0.38 | 0.38 | 0.38 |
| methylbenzimidazole | | | | | | | | | | | | |
| Lamellar clay | 0.82 | 0.85 | 0.89 | 0.85 | 0.78 | 0.80 | 0.80 | 0.68 | 0.69 | 0.78 | 0.63 | 0.73 |
| mineral B1 | | | | | | | | | | | | |
| (indicated as | | | | | | | | | | | | |
| inorganic | | | | | | | | | | | | |
| substance) | | | | | | | | | | | | |
| Photoelectric | 7.2 | 7.0 | 6.9 | 7.0 | 7.1 | 7.0 | 7.0 | 7.2 | 7.1 | 5.8 | 7.0 | 5.7 |
| conversion | | | | | | | | | | | | |
| efficiency (%) | | | | | | | | | | | | |
| Heat resistance | 0.91 | 0.93 | 0.95 | 0.92 | 0.91 | 0.93 | 0.92 | 0.62 | 0.65 | 0.62 | 0.61 | 0.62 |
| (decline ratio) | | | | | | | | | | | | |
| Moisture resistance | 0.65 | 0.66 | 0.65 | 0.66 | 0.65 | 0.64 | 0.65 | 0.66 | 0.65 | 0.61 | 0.66 | 0.60 |
| (decline ratio) | | | | | | | | | | | | |
| Moist heat | 0.60 | 0.61 | 0.60 | 0.60 | 0.61 | 0.60 | 0.61 | 0.45 | 0.43 | 0.38 | 0.45 | 0.38 |
| resistance (decline | | | | | | | | | | | | |
| ratio) | | | | | | | | | | | | |

| | Working Examples | | | | | |
|---|---|---|---|---|---|---|
| | 8 | 9 | 10 | 11 | 12 | 13 |
| Organic salt | 6.00 | 6.00 | 6.00 | 6.00 | 6.00 | 6.00 |
| compound a2-1 | | | | | | |
| Organic salt | 4.00 | 4.00 | 4.00 | 4.00 | 4.00 | 4.00 |
| compound a1-1 | | | | | | |
| Iodine | 0.40 | 0.40 | 0.40 | 0.40 | 0.40 | 0.40 |
| N- | 0.38 | 0.38 | 0.38 | 0.38 | 0.38 | 0.38 |
| methylbenzimidazole | | | | | | |
| Lamellar clay | 0.50 | 0.60 | 0.90 | 1.20 | | |
| mineral B1 | | | | | | |
| (indicated as | | | | | | |
| inorganic | | | | | | |
| substance) | | | | | | |
| Lamellar clay | 0.30 | 0.40 | 0.60 | 0.80 | 1.00 | 2.00 |
| mineral B2 | | | | | | |
| (indicated as | | | | | | |
| inorganic | | | | | | |
| substance) | | | | | | |
| Photoelectric | 5.8 | 6.2 | 6.3 | 6.1 | 5.9 | 6.0 |
| conversion | | | | | | |
| efficiency (%) | | | | | | |
| Heat resistance | 0.89 | 0.90 | 0.92 | 0.93 | 0.90 | 0.88 |
| (decline ratio) | | | | | | |
| Moisture resistance | 0.81 | 0.81 | 0.83 | 0.85 | 0.82 | 0.88 |
| (decline ratio) | | | | | | |
| Moist heat | 0.80 | 0.81 | 0.82 | 0.82 | 0.82 | 0.83 |
| resistance (decline | | | | | | |
| ratio) | | | | | | |

The components shown in Table 1 are as follows.

Organic salt compound a2-1: N-methyl-3-propyl imidazolium iodide (manufactured by Tokyo Chemical Industry Co., Ltd.)

Organic salt compound a2-2: N-methyl-3-methyl imidazolium iodide (synthesized product)

Organic salt compound a2-3: N-methyl-3-ethyl imidazolium iodide (synthesized product)

Organic salt compound a1-1: N-methyl-3-ethylimidazolium thiocyanate (manufactured by Sigma-Aldrich Co. LLC.)

Organic salt compound a1-2: N-methyl-N-methylpyrrolidinium thiocyanate (synthesized product)

Organic salt compound 1: Guanidine thiocyanate (manufactured by Sigma-Aldrich Co. LLC.)

Lamellar clay mineral B1: Synthetic smectite (trade name: Lucentite SPN, manufactured by Co-op Chemical Co., Ltd. (organically modified lamellar clay mineral of organically modified Lucentite SWN (average particle size: 0.02 μm, also manufactured by Co-op Chemical Co., Ltd.)

Lamellar clay mineral B2: Silane-treated organic bentonite treated with quaternary ammonium and alkyltrialkoxysilane (manufactured by Hojun Yoko K.K.)

As is clear from the results shown in Table 1, the electrolytes of Comparative Examples 1 and 4 that were prepared without including the organic salt compound experienced about a 60% decline in photoelectric conversion efficiency after heating and had inferior heat resistance.

Likewise, it is also clear that the electrolytes of Comparative Examples 2, 3, and 5 that were prepared using an organic salt compound other than the organic salt compound (A) experienced about a 60% decline in photoelectric conversion efficiency after heating and had inferior heat resistance.

On the other hand, it is clear that the electrolytes of Working Examples 1 to 13 that were prepared using the organic salt compound (a1) as the organic salt compound (A) displayed the same level of photoelectric conversion efficiency as that of Comparative Example 1, and displayed high photoelectric conversion efficiency after heating and superior heat resistance.

Particularly, it is clear that the electrolytes of Working Examples 8 to 13 that were prepared using the lamellar clay mineral (B) containing an alkylsilyl group displayed not only superior heat resistance, but also superior moisture resistance and superior moist heat resistance.

### EXPLANATIONS OF LETTERS OR NUMERALS

1: Transparent plate
2: Transparent conductive film
3: Oxide semiconductor porous film
4: Photoelectrode
5: Counterelectrode
6: Electrolyte layer
11: Transparent plate
12: Transparent conductive film (ITO, FTO)
13: Metal oxide
14: Electrolyte
15: Platinum film
16: Transparent conductive film (ITO, FTO)
17: Plate
18: Counterelectrode

1. An electrolyte for a photoelectric conversion element comprising an organic salt compound (A) including a tertiary or quaternary cation, wherein
at least an organic salt compound (a1) including a tertiary or quaternary cation and a thiocyanate anion is used as the organic salt compound (A) and wherein
the electrolyte further comprises a lamellar clay mineral (B).

2. (canceled)

3. The electrolyte for a photoelectric conversion element according to claim 1, wherein the lamellar clay mineral (B) comprises an alkylsilyl group.

4. The electrolyte for a photoelectric conversion element according to claim 1, wherein the organic salt compound (A) comprises a cation that is expressed by the following Formula (1) or (2): 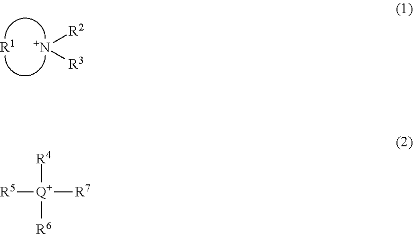
(wherein in Formula (1), R¹ is a hydrocarbon group having from 1 to 20 carbons that may contain a hetero atom, and may include a substituent having 1 to 20 carbons that may contain a hetero atom; R² and R³ are each independently a hydrocarbon group having from 1 to 20 carbons that may contain a hetero atom; however, the R³ moiety is absent if the nitrogen atom includes a double bond; in Formula (2), Q is a nitrogen, oxygen, phosphorus, or sulfur atom; and R⁴, R⁵, R⁶, and R⁷ are each independently a hydrocarbon group having 1 to 8 carbons that may contain a hetero atom; however, the R⁷ moiety is absent if Q is an oxygen or a sulfur atom).

5. A photoelectric conversion element comprising: a photoelectrode including a transparent conductive film and a metal oxide semiconductor porous film;
a counterelectrode disposed opposite the photoelectrode; and
an electrolyte layer disposed between the photoelectrode and the counterelectrode, wherein
the electrolyte layer is an electrolyte for a photoelectric conversion element according to claim 1.

6. A dye-sensitized solar cell comprising the photoelectrode described in claim 5 carrying a photosensitized dye.

7. A photoelectric conversion element comprising: a photoelectrode including a transparent conductive film and a metal oxide semiconductor porous film;
a counterelectrode disposed opposite the photoelectrode; and
an electrolyte layer disposed between the photoelectrode and the counterelectrode, wherein
the electrolyte layer is an electrolyte for a photoelectric conversion element according to claim 3.

8. A dye-sensitized solar cell comprising the photoelectrode described in claim 7 carrying a photosensitized dye.

9. A photoelectric conversion element comprising: a photoelectrode including a transparent conductive film and a metal oxide semiconductor porous film;
a counterelectrode disposed opposite the photoelectrode; and
an electrolyte layer disposed between the photoelectrode and the counterelectrode, wherein
the electrolyte layer is an electrolyte for a photoelectric conversion element according to claim 4.

10. A dye-sensitized solar cell comprising the photoelectrode described in claim 9 carrying a photosensitized dye.

11. The electrolyte for a photoelectric conversion element according to claim 3, wherein the organic salt compound (A) comprises a cation that is expressed by the following Formula (1) or (2): 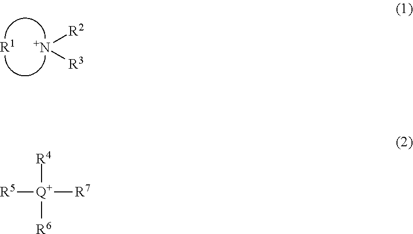
(wherein in Formula (1), R¹ is a hydrocarbon group having from 1 to 20 carbons that may contain a hetero atom, and may include a substituent having 1 to 20 carbons that may contain a hetero atom; R² and R³ are each independently a hydrocarbon group having from 1 to 20 carbons that may contain a hetero atom; however, the R³ moiety is absent if the nitrogen atom includes a double bond; in Formula (2), Q is a nitrogen, oxygen, phosphorus, or sulfur atom; and R⁴, R⁵, R⁶, and R⁷ are each independently a hydrocarbon group having 1 to 8 carbons that may contain a hetero atom; however, the R⁷ moiety is absent if Q is an oxygen or a sulfur atom).

12. A photoelectric conversion element comprising: a photoelectrode including a transparent conductive film and a metal oxide semiconductor porous film;
a counterelectrode disposed opposite the photoelectrode; and
an electrolyte layer disposed between the photoelectrode and the counterelectrode, wherein
the electrolyte layer is an electrolyte for a photoelectric conversion element according to claim 11.

13. A dye-sensitized solar cell comprising the photoelectrode described in claim 12 carrying a photosensitized dye.

14. The dye-sensitized solar cell according to claim 6, wherein the photosensitized dye includes a metal complex on which a thiocyanate anion is coordinated.

15. The dye-sensitized solar cell according to claim 8, wherein the photosensitized dye includes a metal complex on which a thiocyanate anion is coordinated.

16. The dye-sensitized solar cell according to claim 10, wherein the photosensitized dye includes a metal complex on which a thiocyanate anion is coordinated.

17. The dye-sensitized solar cell according to claim 13, wherein the photosensitized dye includes a metal complex on which a thiocyanate anion is coordinated.
